(19) United States
(12) Patent Application Publication
(10) Pub. No.: US 2008/0029865 A1
(43) Pub. Date: Feb. 7, 2008

(54) Electronic Device and Method For Producing the Same

(75) Inventors: Michael Bauer, Nittendorf (DE); Christian Stuempfl, Schwandorf (DE); Ludwig Heitzer, Regensburg (DE)

Correspondence Address: EDELL , SHAPIRO & FINNAN , LLC, 1901 RESEARCH BOULEVARD , SUITE 400, ROCKVILLE, MD, 20850, US

(73) Assignee: INFINEON TECHNOLOGIES AG, Neubiberg (DE)

(21) Appl. No.: 11/760,819

(22) Filed: Jun. 11, 2007

(30) Foreign Application Priority Data
Jun. 9, 2006 (DE) 10 2006 027 283.8

(51) Int. Cl. H01L 21/98; H01L 23/02

(52) U.S. Cl. 257/684; 438/108; 257/E23.18; 257/E21.532

(57) ABSTRACT

An electronic device is produced by providing a carrier wafer formed from at least a semiconductor material, apply a wiring structure with conductor tracks and contact pads to a top side of the carrier wafer so as to form a plurality of semiconductor device positions arranged in rows and columns along the carrier wafer. Integrated circuit chips are applied in the semiconductor device positions and embedded into a plastic housing composition, thereby forming a composite plate including the integrated circuit chips and the plastic housing composition. After curing the plastic housing composition, the carrier wafer is removed.

### CROSS REFERENCE TO RELATED APPLICATIONS

This application claims priority under 35 U.S.C. §119 to Application No. DE 102006027283.8 filed on Jun. 9, 2006, entitled “Method for Producing a Semiconductor Device,” the entire contents of which are hereby incorporated by reference.

### BACKGROUND

So-called “embedded dielectric” technologies, in which one or ever a plurality of semiconductor chips and, if appropriate, further components are surrounded with a plastic housing by techniques such as introduction by molding, introduction by lamination or layer-by-layer construction of the plastic, have numerous advantages over conventional technologies in which the semiconductor chip is applied to a substrate by means of contacts such as solder balls and is subsequently surrounded with a plastic housing.

Thus, they permit for example smaller and lighter devices and enable the fixed connection of a plurality of chips in a single housing and also a higher density of electrical connections.

Moreover, the “embedded dielectric” technologies afford advantages during production. A semiconductor device is known, for the production of which semiconductor chips are processed to form a composite plate or a panel by introduction into a plastic composition by molding, wherein the active top sides of the semiconductor chips form a coplanar area with the top side of the composite plate, while their edges and the rear side are covered by the plastic housing composition. A wiring structure having conductor tracks separated from one another by dielectric layers can be applied comparatively simply to the coplanar area, which affords a planar surface for process steps such as photolithography steps.

What is problematic in this case, however, is that warpage of the composite plate that are caused by different coefficients of thermal expansion of semiconductor material and plastic housing composition destroy the planarity of the surface. During the application of the rewiring structure, this results in losses in the accuracy with which structures such as contact areas and conductor tracks can be applied. Consequently, only a limited density of electrical connections is possible.

### SUMMARY

An electric device is produced as described herein and includes a wiring structure with particularly high accuracy on the surface of an integrated circuit chip using “embedded dielectric technology”. A carrier wafer is provided comprising a semiconductor material. A wiring structure with conductor tracks and contact pads is applied to a top side of the carrier wafer, thereby providing a plurality of semiconductor device positions arranged in rows and columns. Subsequently, integrated circuit chips are applied in the semiconductor device positions and embedded into a plastic housing composition, thereby forming a composite plate including the integrated circuit chips and the plastic housing composition. After curing the plastic housing composition, the carrier wafer is removed.

The above and still further features and advantages of the electronic device and method will become apparent upon consideration of the following definition, description and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

Exemplary embodiments are explained in more detail below with reference to the accompanying figures, where:

FIGS. 1A-1F shows various steps of a first embodiment of the method; and

FIGS. 2-2E shows various steps of a second embodiment of the method.

Identical parts are provided with the same reference symbols in all of the figures.

### DETAILED DESCRIPTION

As described herein, rewiring structures can be applied with particularly high accuracy. An exemplary method for producing an electronic device (e.g., semiconductor device), as described herein, includes providing a carrier wafer comprising a semiconductor material having a top side and an underside. A typical wiring structure including at least one rewiring layer with metallic conductor tracks and contact pads is applied to the top side of the carrier wafer, wherein device positions arranged in tows and columns are provided. The entire wiring structure can immediately be tested in the wafer assemblage as required. As a result, defective device positions can already be identified at a very early stage of production and, if appropriate, be marked and not populated with an integrated circuit chip (e.g., semiconductor chip). After the application and, if appropriate, also the testing of the wiring structure, semiconductor chips are applied to the top side—provided with the wiring structure—of the carrier wafer in the device positions. It is also possible to provide a plurality of integrated circuit chips for the formation of a multichip module or else further components per device position.

After the application and fixing of the chips in the device positions, a plastic housing composition is applied to the top side of the carrier wafer and embeds the integrated circuit chips into the housing composition, thereby forming a composite plate comprising integrated circuit chips and plastic housing composition. After the curing of the housing composition, the composite plate is stable and self-supporting, such that the carrier wafer can be removed and the wiring structure remains of the composite plate.

Warped areas are not suitable for the application of wiring structures having particularly high density therefore requiring a particularly high accuracy. On the other hand, however, warpage of the composite plate can only be minimized with comparatively high outlay and cannot be completely suppressed. Therefore, the wiring structure should not be applied directly to the composite plate, abut rather first to a carrier wafer. A carrier wafer composed of metal would be conceivable, in principle, but is disadvantageous owing to its high production costs. The necessary removal of the carrier wafer would also have to be carried out completely via etching in the case of a metallic carrier wafer and would therefore by very time-consuming and costly. Moreover, many adhesives used for fixing the semiconductor chips, for example, exhibit only inadequate adhesion on metallic surfaces.

With a carrier wafer comprising a semiconductor material, however, these problems can be solved since a semiconductor wafer would not have to be produced separately as a carrier wafer. Rather, wafers constituting rejects from semiconductor chip production, for example, could be used as a carrier wafer. Semiconductor wafers can be patterned very well and simply via proven processes, which results in a high density of the structures produced, In addition, semiconductor wafers can be removed very simply, rapidly and cost-effectively by thinning via grind and/or etching, the risk of inadvertent damage to the wiring structure being particularly how due to the differing etchability of the carrier wafer and the wiring structure. Since the carrier wafer comprises a single material, warpage during the production process in negligible.

The semiconductor chips typically have an active top side with integrated circuits and contact areas and a passive rear side. In one embodiment, the semiconductor chips are mounted by their active top side onto the contact pads on the top side of the carrier wafer using flip-chip technology. For this purpose, the contact pads can be reinforced galvanically or in electroless fashion, or be provided with solder balls, prior to the application of the semiconductor chips.

In an alternate embodiment, the semiconductor chips can also be mounted by their rear sides onto the top side of the carrier wafer. In this case, contact areas on their active top side are electrically connected to the contact pads on the carrier wafer via bonding wires.

The semiconductor chips can be connected to the wiring structure on the carrier wafer via a soldering process. Alternatively, it is also possible for the semiconductor chips to be connected to the wiring structure on the carrier wafer via adhesive bonding, alloying or thermocompression welding.

The plastic housing composition embeds the semiconductor chips in such a way that the latter, if appropriate apart from the side connected to the wiring structure, are completely enclosed by the plastic housing composition. For this purpose, the plastic housing composition can be applied to the semiconductor chips and to the carrier wafer via compression molding or else via spin-on methods or jet printing methods.

Once the plastic housing composition has cured, it forms together with the semiconductor chips a self-supporting composite plate. After the application of the plastic housing composition, therefore, a composite body composed of the carrier wafer and the composite plate having the semiconductor chips embedded into the plastic housing composition has formed, wherein the composite plate is arranged on the top side—provided with the wiring structure—of the carrier wafer in such a way that the semiconductor chips embedded into the plastic housing composition are applied in the device positions.

After the curing of the plastic housing composition, the carrier wafer can be removed, for example, by thinning via grinding or etching or via a combination of both. This is particularly simple because the semiconductor material of the carrier wafer can be machined comparatively easily via standard processes. The composite plate remains, and its side formerly facing the carrier wafer is a coplanar area composed of surfaces of the (semiconductor chips arranged in the device positions, comprising plastic housing composition and including the wiring structure with conductor tracks, contact pads and, if appropriate, a dielectric. Thus, the metallization with which the semiconductor chip is now provided is uncovered during the removal of the carrier wafer. Contact pads of the metallization can either be used directly as external contacts if the semiconductor devices are those having so-called leadless packages. However, the uncovered contact pads can also be reinforced galvanically or in electroless fashion, or be provided with solder balls.

The composite plate is typically singulated into semiconductor devices via a sawing process, for example, after the removal of the carrier wafer. However, it is also possible, for example, if the individual semiconductor devices are intended to have additional stability for further processing or for transport, to singulate the composite plate into semiconductor devices prior to the removal of the carrier wafer.

The method provides a number of advantages, including the feature of being carried out simply and at the wafer level in front end processes and are therefore highly cost-effective. Via the carrier wafer comprising a semiconductor material with at most minimal warpage, the method enables a very high accuracy in applying the rewiring structure, the accuracy being limited practically only by the accuracy with which the semiconductor chips are deposited during placement. As a result, with the method, it is possible on the one hand to achieve very high device densities on a single semiconductor wafer, and on the other hand semiconductor devices with a particularly high density of metallic structures such as connections, for example, can be produced with comparatively low outlay.

Exemplary embodiments are described in greater detail below with reference to the figures.

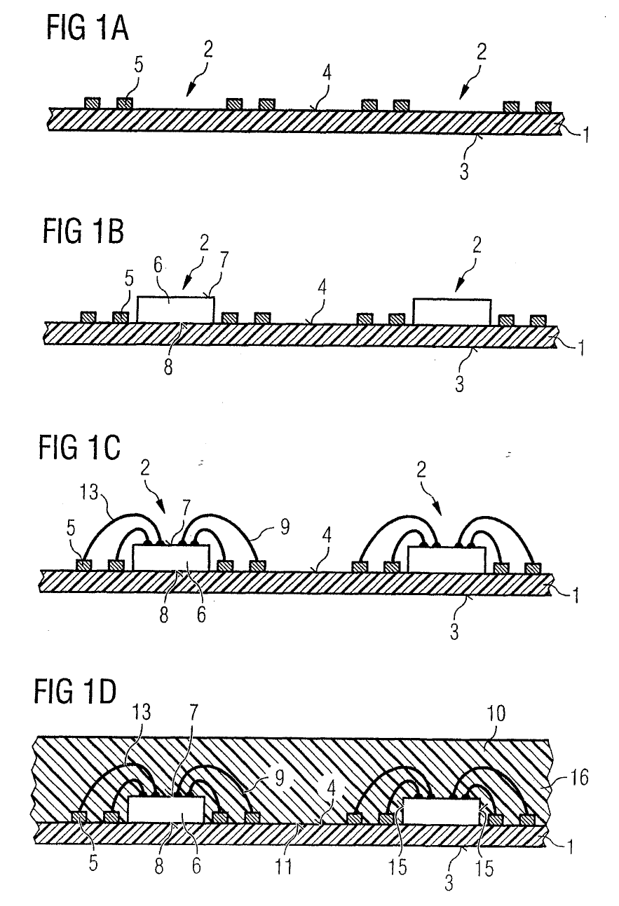

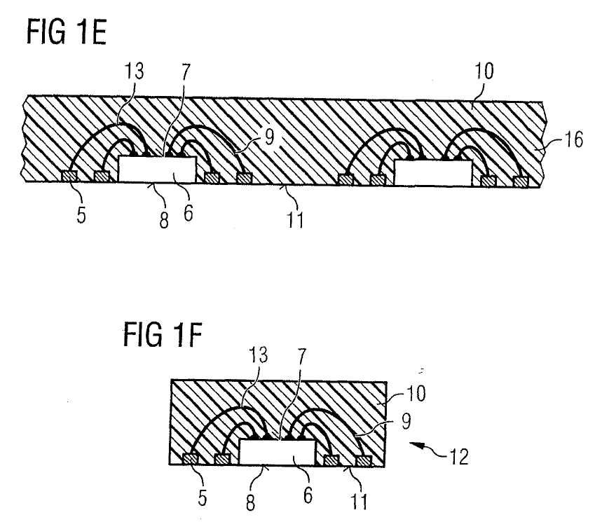

FIG. 1A shows a first step in a method for producing an electronic device (e.g., a semiconductor device). The carrier wafer 1 that comprises, for example, a semiconductor material, includes a rear side 3 and a top side 4. In this step, a wiring structure 5 comprising contact pads (e.g., bonding pads), is applied to the top side 4 of the carrier wafer 1. Device positions 2 are provided in rows and columns on the carrier wafer 1.

The wiring structure 5 is produced by customary process such as photolithography and deposition of metals. The wiring structure 5 may include, for example, contact pads and conductor tracks and also a plurality of wiring layers. Only the contact pads are indicated schematically in the figure, for the sake of clarity. Since the carrier wafer 1 in principle comprises a single material, e.g., a semiconductor material, and does not constitute a composite of materials having different coefficients of thermal expansion, it experiences only negligible warpage in the event of temperature fluctuations occurring during different process steps. The wiring structure 5 can therefore be applied to its top side 4 with particularly high accuracy and therefore also with particularly high density.

FIG. 1B illustrates how the integrated circuit chips 6 (e.g., semiconductor chips) are arranged in the device positions 2. In the exemplary embodiment shown, the integrated circuit chips 6 are fixed by their passive rear sides 8 on the carrier wafer 1 or on the wiring structure 5. They have contact areas (not illustrated) on their active top sides 7.

As shown in FIG. 1C, the contact areas are electrically connected to the corresponding contact pads of the wiring structure 5 via connecting elements 9, in this case, for example, bonding wires 13.

FIG. 1D shows a next step of the method, in which the integrated circuit chips 6 are surrounded with a plastic housing composition 10. In this case, the edge sides 15 and the active top sides 7 of the integrated circuit chips 6 are completely embedded into the plastic housing composition 10. A composition plate 16 composed of the plastic housing composition 10, the integrated circuit chips 6 and also the wiring structure 5 is formed, which bears by its underside 11 on the top side 4 of the carrier wafer 1.

After the curing of the plastic housing composition 10, the composite plate 16 is self-supporting and so stable that the carrier wafer 1 can be removed. This is done, for example, by grinding away and/or etching the carrier wafer 1 is illustrated in FIG. 1E. It can then be singulated into individual electronic devices 12 in accordance with FIG. 1F (e.g., via sawing). Such a semiconductor device has, on its now accessible underside 11, contact pads of the wiring structure 5, which, if appropriate, can also be reinforced galvanically or in electroless fashion to form external contacts.

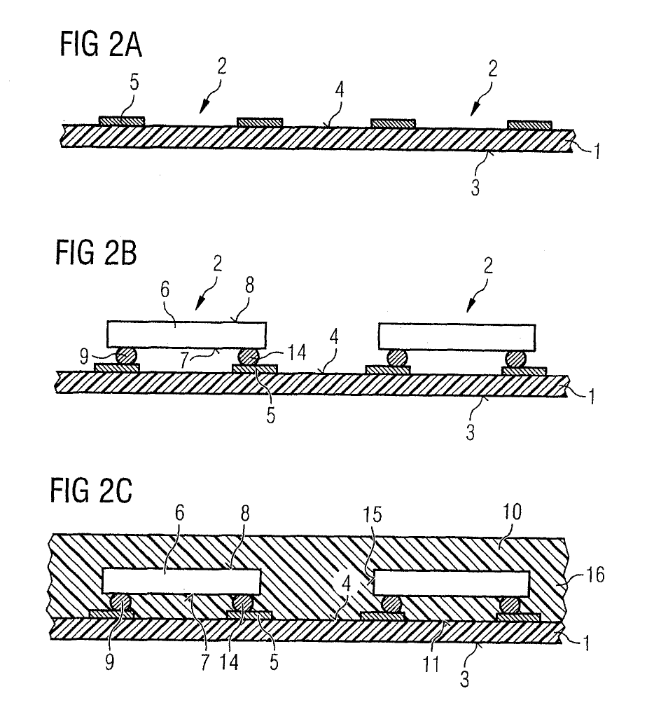

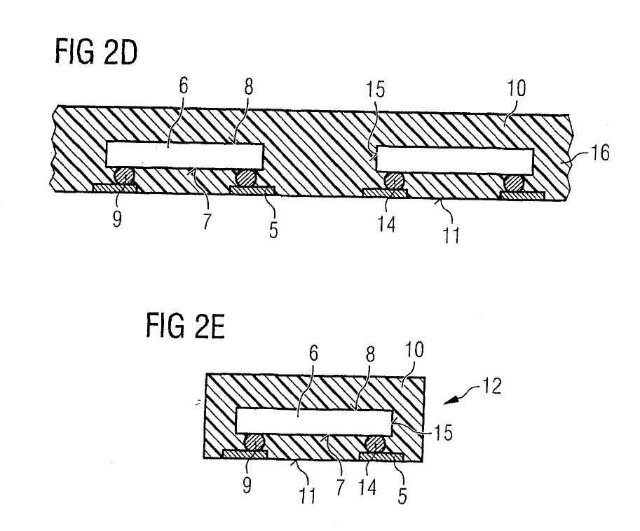

A second embodiment of the method is illustrated in FIG. 2. Referring to FIG. 2A, a wiring structure 5 in this case likewise applied to a carrier wafer 1 comprising, for example, a semiconductor material.

As shown in FIG. 2B, the integrated circuit chips 6 are applied to the wiring structure 5 in device positions 2 arranged in rows and columns, using flip-chip technology. For this purpose, the integrated circuit chips 6 have, on their active top sides 7, connecting elements 9 in the form of solder balls 14 via which they are electrically connected to contact pads of the wiring structure 5. In the case of this embodiment, therefore, the active top side 7 of the integrated circuit chips 6 faces the carrier wafer 1.

As illustrated in FIG. 2C, a plastic housing composition 10 is subsequently applied, which completely embeds the integrated circuit chips 6. The composite plate 16 that is formed bears with its underside 11 on the top side 4 of the carrier wafer 1.

When the carrier wafer 1 is subsequently removed, as shown in FIG. 2D, the external contact area of the wiring structure are uncovered at the underside 11 and form external contacts or can be reinforced to form external contacts before or after singulation into electronic devices. An electronic device 12 singulated from the composite plate 16 is shown in FIG. 2E.

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed:

1. A method for producing an electronic device, the method comprising:
applying a wiring structure including conductor tracks and contact pads on a top side of the carrier wafer, the carrier wafer comprising a semiconductor material, so as to define a plurality of device positions arranged i rows and columns along the carrier wafer;
applying integrated circuit chips to the top side of the carrier wafer in the device positions;
applying a plastic housing composition to the top side of the carrier wafer and embedding the integrated circuit chips in the housing composition so as to form a composite plate including the integrated circuit chips and the housing composition.

2. The method according to claim 1, wherein the integrated circuit chips are applied to the top side of the carrier wafer by mounting the integrated circuit chips onto the contact pads on the top side of the carrier wafer via a flip-chip connection.

3. The method according to claim 1, wherein the integrated circuit chips are applied to the top side of the carrier wafer by mounting the integrated circuit chips onto the top side of the carrier wafer and electrically connecting the integrated circuit chips to the contact pads via bonding wires.

4. The method according to claim 1, further comprising:
reinforcing the contact pads galvanically or in an electroless manner prior to applying the integrated circuit chips.

5. The method according to claim 1, further comprising:
curing the housing composition; and
removing the carrier wafer.

6. The method according to claim 5, further comprising:
reinforcing the contact pads galvanically or in an electroless manner after removal of the carrier wafer.

7. The method according to claim 5, further comprising:
singulating the composite plate at locations between integrated circuit chips as to form individual electronic devices.

8. The method according to claim 5, wherein the carrier wafer is removed via grinding or etching.

9. The method according to claim 1, further comprising:
connecting the integrating circuit chips to the wiring structure via soldering.

10. The method according to claim 1, further comprising:
connecting the integrated circuit chips to the wiring structure via adhesive bonding.

11. The method according to claim 1, further comprising:
connecting the integrated circuit chips to the wiring structure via alloying.

12. The method according to claim 1, further comprising:
connecting the integrated circuit chips to the wiring structure via thermocompression welding.

13. The method according to claim 1, wherein the housing composition is applied via compression molding.

14. The method according to claim 1, wherein the housing composition is applied via a spin-on method.

15. The method according to claim 1, wherein the housing composition is applied via a jet printing method.

16. The method according to claim 1, wherein each of the integrated circuit chips a semiconductor material.

17. A composite body, comprising:
a carrier wafer comprising a semiconductor material and including a plurality of wiring structures arranged in rows and columns on a top side of the carrier wafer that define device positions along the carrier wafer;
a plurality of integrated circuit chips secured at the device positions; and
a plastic housing composition secured to the carrier wafer and embedding the integrated circuit chips.

18. The composite body according to claim 17, wherein each of the integrated circuit chips comprises a semiconductor material.
